(19) United States
(12) Patent Application Publication
(10) Pub. No.: US 2012/0299087 A1
(43) Pub. Date: Nov. 29, 2012

(54) NON-VOLATILE MEMORY DEVICE AND METHOD FOR FABRICATING THE SAME

(76) Inventors: Han-Soo JOO, Gyeonggi-do (KR); Yu-Jin PARK, Gyeonggi-do (KR)

(21) Appl. No.: 13/334,017

(22) Filed: Dec. 21, 2011

(30) Foreign Application Priority Data
May 26, 2011 (KR) 10-2011-0050038

(51) Int. Cl. H01L 29/792; H01L 21/336

(52) U.S. Cl. 257/326; 438/287; 257/E29.309; 257/E21.423

(57) ABSTRACT

A non-volatile memory device includes gate structures including first insulation layers that are alternately stacked with control gate layers over a substrate, wherein the gate structures extend in a first direction, channel lines that each extend over the gate structures in a second direction different from the first direction, a memory layer formed between the gate structures and the channel lines and arranged to trap charges by electrically insulating the gate structures from the channel lines, bit line contacts forming rows that each extend in the first direction and contacting top surfaces of the channel lines, source lines that each extend in the first direction and contact the top surfaces of the channel lines, wherein the source lines alternate with the rows of bit line contacts, and bit lines that are each formed over the bit line contacts and extend in the second direction.

### CROSS-REFERENCE TO RELATED APPLICATIONS

The present application claims priority of Korean Patent Application No. 10-2011-0050038, filed on May 26, 2011, which is incorporated herein by reference in its entirety.

### BACKGROUND

1. Field

Exemplary embodiments of the present invention relate to a non-volatile memory device and a method for fabricating the same, and more particularly, to a non-volatile memory device including a plurality of memory cells that are stacked perpendicularly to a substrate, and a method for fabricating the non-volatile memory device.

2. Description of the Related Art

A non-volatile memory device is a memory device that retains data stored therein although a power supply is cut off. An exemplary non-volatile memory device is a NAND-type flash memory device.

As the integration of a memory device having a two-dimensional structure where memory cells are formed in a single layer over a silicon substrate is reaching physical limits, a non-volatile memory device having a three-dimensional structure where a plurality of memory cells are stacked perpendicularly to a silicon substrate has been developed.

The non-volatile memory device having a three-dimensional structure is fabricated by etching a plurality of insulation layers and a plurality of control gate layers that are alternately stacked over a substrate to form vertical channels and thereby forming trenches for channels, forming a memory layer on the internal walls of each of the trenches for channels, and filling the trenches for channels with a channel layer.

Here, in the process of forming the trenches for channels to form the vertical channels, the width of each of the trenches for channels becomes narrower as it extends to the bottom of the trench when the etch process is performed to form the trenches for channels having a high aspect ratio and the varying width makes the channel width less uniform. As a result, the threshold voltage of the memory cells becomes less uniform as well, and controlling the threshold voltage becomes difficult.

As the number of the stacked memory cells increases, the above-mentioned features become more pronounced.

### SUMMARY

An exemplary embodiment of the present invention is directed to a non-volatile memory device which has an increased integration degree as a plurality of memory cells are stacked in a vertical direction and has a threshold voltage controllable as channels are formed to have a uniform width, and a method for fabricating the non-volatile memory device.

In accordance with an exemplary embodiment of the present invention, a non-volatile memory device includes: gate structures including first insulation layers that are alternately stacked with control gate layers over a substrate, wherein the gate structures extend in a first direction; channel lines that each extend over the gate structures in a second direction different from the first direction; a memory layer formed between the gate structures and the channel lines and arranged to trap charges by electrically insulating the gate structures from the channel lines; bit line contacts forming rows that each extend in the first direction and contact top surfaces of the channel lines; source lines that each extend in the first direction and contact the top surfaces of the channel lines, wherein the source lines alternate with the rows of bit line contacts; and bit lines that are formed over the bit line contacts and each extend in the second direction.

In accordance with another exemplary embodiment of the present invention, a method for fabricating a non-volatile memory device includes: alternately stacking first insulation layers with control gate layers over a substrate; forming a plurality of gate structures that each extend in a first direction by selectively etching the first insulation layers and the control gate layers; forming a memory layer along the gate structures; forming a channel layer over the memory layer; forming channel lines that each extend in a second direction different from the first direction by selectively etching the channel layer; forming source lines that each extend in the first direction and contact the top surfaces of the channel lines; forming bit line contacts in rows that each extend in the first direction, wherein the rows of bit line contacts contact the top surfaces of the channel lines and alternate with the source lines; and forming bit lines that each extend in the second direction over the bit line contacts.

In accordance with yet another exemplary embodiment of the present invention, a non-volatile memory device includes: a pair of gate structures including first insulation layers that are alternately stacked with control gate layers over a substrate and each extend in a first direction; a second insulation layer disposed between the pair of gate structures; channel lines that each extend along the pair of gate structures and the second insulation layer in a second direction different from the first direction; a memory layer disposed between the pair of gate structures and the second insulation layer as a whole and the channel lines to trap charges by electrically insulating the gate structures from the channel lines; bit line contacts forming rows that each extend in the first direction and contacting top surfaces of the channel lines; source lines that each extend in the first direction and contact the top surfaces of the channel lines, wherein the source lines alternate the rows of bit line contacts; and bit lines that are formed over the bit line contacts and each extend in the second direction.

In accordance with still another exemplary embodiment of the present invention, a method for fabricating a non-volatile memory device includes: alternately stacking first insulation layers with control gate layers over a substrate; forming a plurality of gate structures that each extend in a first direction by selectively etching the first insulation layers and the control gate layers; filling a space between the gate structures with a second insulation layer; forming a memory layer along the gate structures and the second insulation layer; forming a channel layer over the memory layer; forming channel lines that each extend in a second direction different from the first direction by selectively etching the channel layer; forming source lines that each extend in the first direction and contact the top surfaces of the channel lines; forming bit line contacts in rows that that each extend in the first direction, wherein the rows of bits lines contact the top surfaces of the channel lines and alternate with the source lines; and forming bit lines that each extend in the second direction over the bit line contacts.

### BRIEF DESCRIPTION OF THE DRAWINGS

FIGS. 1 to 6 are perspective views illustrating a method for fabricating a non-volatile memory device in accordance with a first exemplary embodiment of the present invention.

FIG. 7 is a perspective view illustrating a non-volatile memory device in accordance with a second exemplary embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

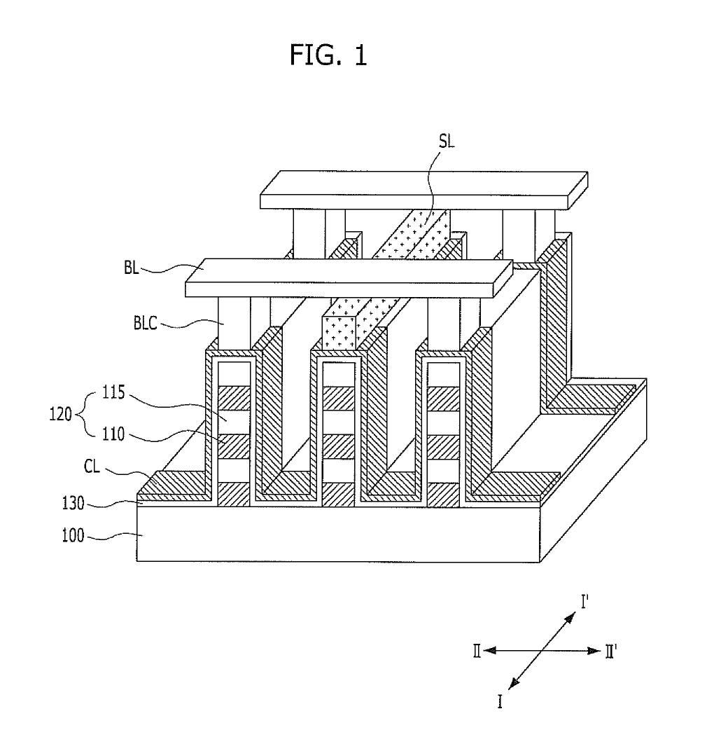

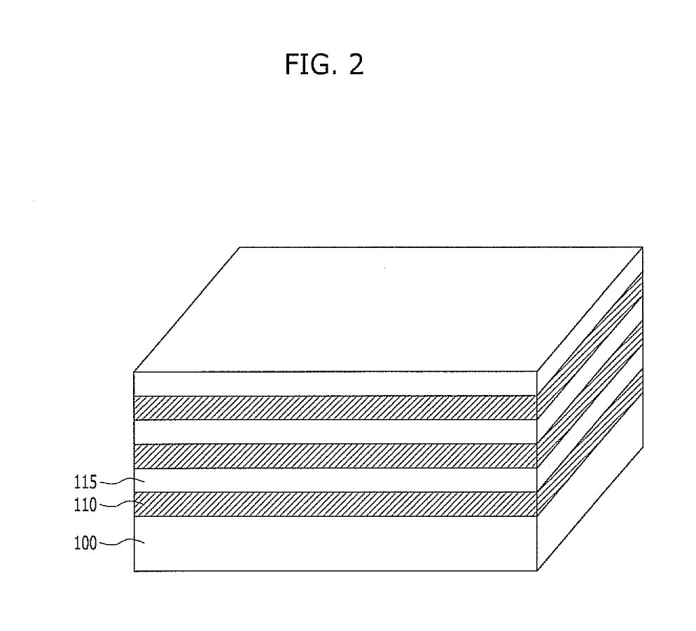

FIGS. 1 to 6 are perspective views illustrating a method for fabricating a non-volatile memory device in accordance with a first exemplary embodiment of the present invention. In particular, FIG. 1 shows a non-volatile memory device fabricated in accordance with the first exemplary embodiment of the present invention, and FIGS. 2 to 6 illustrate intermediate processes for fabricating the non-volatile memory device shown in FIG. 1.

In the first place, the non-volatile memory device in accordance with the first exemplary embodiment of the present invention is described.

Referring to FIG. 1, the non-volatile memory device includes a substrate 100, gate structures 120, channel lines CL, a memory layer 130, bit line contacts BLC, source lines SL, and bit lines BL. Each gate structure 120 includes first insulation layers 110 and control gate layers 115 that are alternately stacked over the substrate 100 and stretched in first direction I-I′. The channel lines CL are stretched along the gate structure 120 in second direction II-II′ which crosses the first direction, for example, perpendicularly. The memory layer 130 is interposed between the gate structures 120 and the channel lines CL and includes a charge blocking layer, a charge trapping layer, and a tunnel insulation layer. The bit line contacts BLC are arrayed in the first direction and contact the top surfaces of the channel lines CL. The source lines SL extend in the first direction, contact the top surfaces of the channel lines CL, and are alternately disposed with rows of the bit line contacts BLC that each extend in the first direction. The bit lines BL are formed over the bit line contacts and extend in the second direction.

Here, a memory cell includes a control gate layer 115, a channel line contacting the control gate layer 115, and the memory layer 130 interposed between the control gate layer 115 and the channel line CL. In other words, a memory cell is formed between each corresponding control gate layer 115 and a channel line coupled to the control gate layer. Thus, a plurality of memory cells that are arrayed in the first and second directions and stacked in a vertical direction are formed. The memory cells that are arrayed in the first direction and coupled with the control gate layer 115 in the same layer constitute one page, and the memory cells that are coupled with the same channel line constitute one string.

The substrate 100 may be a semiconductor substrate such as a silicon substrate.

In the gate structure 120, the number of stacked control gate layers 115 equal the number of stacked memory cells. The control gate layer 115 may be formed of a P-type polysilicon. A first insulation layer 110 electrically isolates the vertically-stacked memory cells from each other, where, according to an example, it may be an oxide layer. The gate structures 120 may be spaced apart from one another horizontally.

The channel lines CL are extended in the second direction and spaced apart from one another horizontally. The number of channel lines CL may equal the number of memory strings to be formed. The channel lines CL may be a polysilicon layer doped with a P-type impurity or an N-type impurity.

According to the first exemplary embodiment, pillar-type channels are formed not by forming trenches for channels and then filling the trenches for channels with a channel layer but by forming the channel lines in the form of a film, where the channel width of the formed channels is uniform and accordingly, threshold voltages of memory cells may be controlled relatively easily. For example, the film for forming the channel lines is formed over the memory layer 130 by forming a film over the memory layer 130 without completely filling the trenches between the parallel gate structures 120.

The memory layer 130 is interposed between the gate structures 120 and the channel lines CL. Furthermore, the memory layer 130 may be disposed between the channel lines CL and the substrate 100. The memory layer 130 traps charges and substantially stores data while electrically insulating the gate structure 120 from the channel lines.

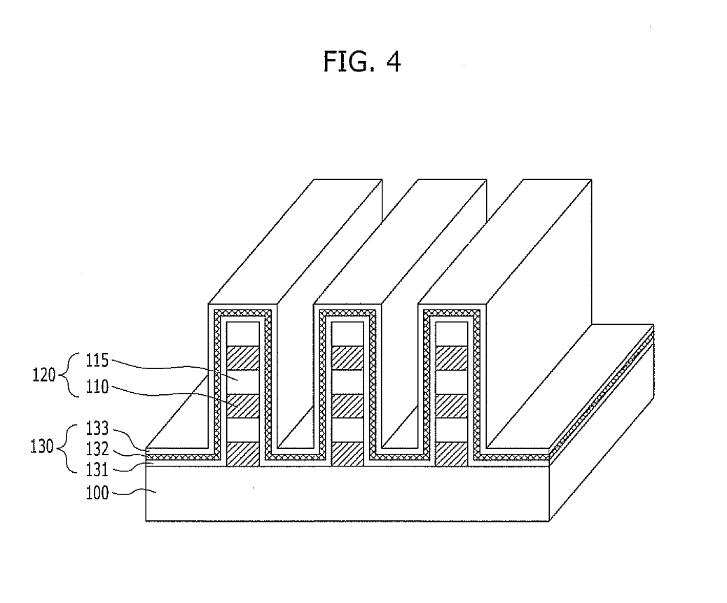

The memory layer 130 may have a structure of triple layers of a charge blocking layer 131, a charge trapping layer 132, and a tunnel insulation layer 133 (see FIG. 4). The charge blocking layer 131 is disposed adjacent to the substrate 100 and the gate structures 120 and may be an oxide layer such as a silicon oxide (SiO₂) layer or an aluminum oxide (Al₂O₃) layer. The tunnel insulation layer 133 is disposed adjacent to the channel lines CL and may be an oxide layer. The charge trapping layer 132 is disposed between the charge blocking layer 131 and the tunnel insulation layer 133 and may be a nitride layer.

The source lines SL may extend in the first direction and directly contact the top surface of the channel lines CL. Here, the top surfaces of the channel lines CL indicate the portion of each channel line formed over the top portion of the uppermost control gate layer 115. The source lines SL are disposed alternately with the rows of the bit line contacts BLC that are arrayed in the first direction.

The source lines SL may be formed of a metal having a relatively small resistance. Current flow may improve when the source lines SL are formed of metal such as tungsten, where tungsten has a smaller resistivity than polysilicon.

The bit line contacts BLC are disposed on the top surfaces of channel lines CL where the source lines SL are not formed. As described above, the bit line contacts BLC in a row that are arrayed in the first direction are referred to as a first-direction row of bit line contacts BLC, where the first-direction rows of bit lines contacts are alternately disposed with the source lines SL.

The bit lines BL are formed over the bit line contacts BLC and extend in the second direction to cross the source lines SL. A plurality of bit lines BL may be disposed in parallel to each other.

Hereafter, a method for fabricating the non-volatile memory device is described.

FIGS. 2 to 6 illustrate a process for fabricating the non-volatile memory device in accordance with the first exemplary embodiment of the present invention. In FIGS. 2 to 6, the elements that are the same as the elements in FIG. 1 are denoted using the same reference characters, and any further description thereof is omitted as being redundant.

Referring to FIG. 2, a plurality of first insulation layers 110 and a plurality of control gate layers 115 are alternately stacked over a substrate 100.

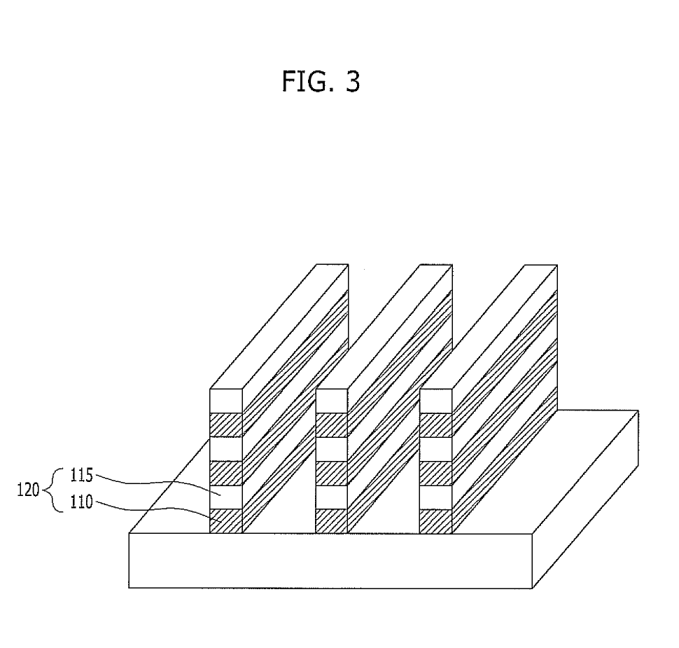

Referring to FIG. 3, gate structures 120 extending in the first direction are formed by selectively etching the first insulation layers 110 and the control gate layers 115. The gate structures 120 may be formed in parallel to each other with a space between them.

Referring to FIG. 4, a memory layer 130 is formed over the gate structures 120 and the substrate 100 that is exposed as a result of the etch process shown in FIG. 3. The memory layer 130 may be formed by sequentially stacking a charge blocking layer 131, a charge trapping layer 132, and a tunnel insulation layer 133 over the substrate 100 and the gate structures 120.

Hereafter, the charge blocking layer 131, the charge trapping layer 132, and the tunnel insulation layer 133 are collectively referred to as a memory layer 130.

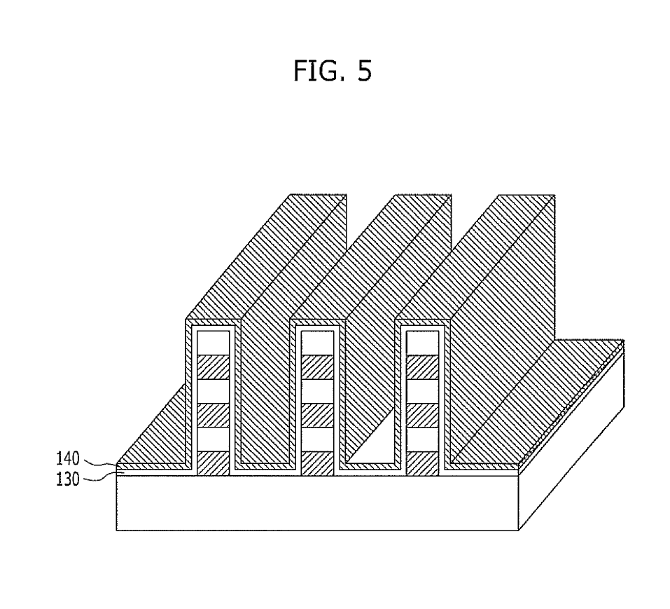

Referring to FIG. 5, a channel layer 140 is formed over the memory layer 130.

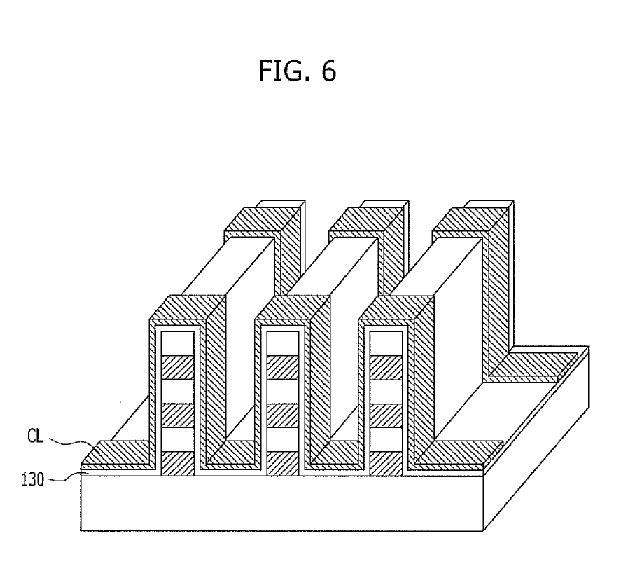

Referring to FIG. 6, channel lines CL stretched in a second direction II-II′ are formed by selectively etching the channel layer 140. The channel lines CL may be spaced apart from each other horizontally.

Referring back to FIG. 1, source lines SL, bit line contacts BLC, and bit lines BL are formed over the channel lines CL.

More specifically, trenches (not shown) are formed in the region where the source lines SL are to be subsequently formed, where the trench formation includes forming a third insulation layer (not shown) covering the substrate structure including the channel lines CL formed therein and selectively etching the third insulation layer. Subsequently, the source lines SL are formed by filling the trenches with a conductive material for forming the source lines with a metal such as tungsten.

Subsequently, trenches (not shown) are formed on the top surface of the channel lines CL without source lines SL formed thereon, where bit line contacts BLC are to be formed thereon, by forming a fourth insulation layer (not shown) covering the substrate structure including the source lines SL and subsequently selectively etching the third insulation layer and the fourth insulation layer. Subsequently, bit line contacts BLC are formed by filling the trenches for forming the bit line contacts BLC with a conductive material.

Subsequently, trenches (not shown) are formed in the region where bit lines are to be formed, by forming a fifth insulation layer (not shown) covering the substrate structure including the bit line contacts BLC formed therein and selectively etching the fifth insulation layer. Subsequently, bit lines BL are formed by filling the trenches for forming the bit lines BL with a conductive material.

After performing any of the process of FIG. 5, the process of FIG. 6, or the formation of trenches for source lines SL and the trenches for bit line contacts BLC, an ion implantation process may be performed on the channel layer 140 or the top surface of the channel lines CL. The implantation of impurity ions may form junctions on the channel lines CL contacting the source lines SL and the bit line contacts BLC.

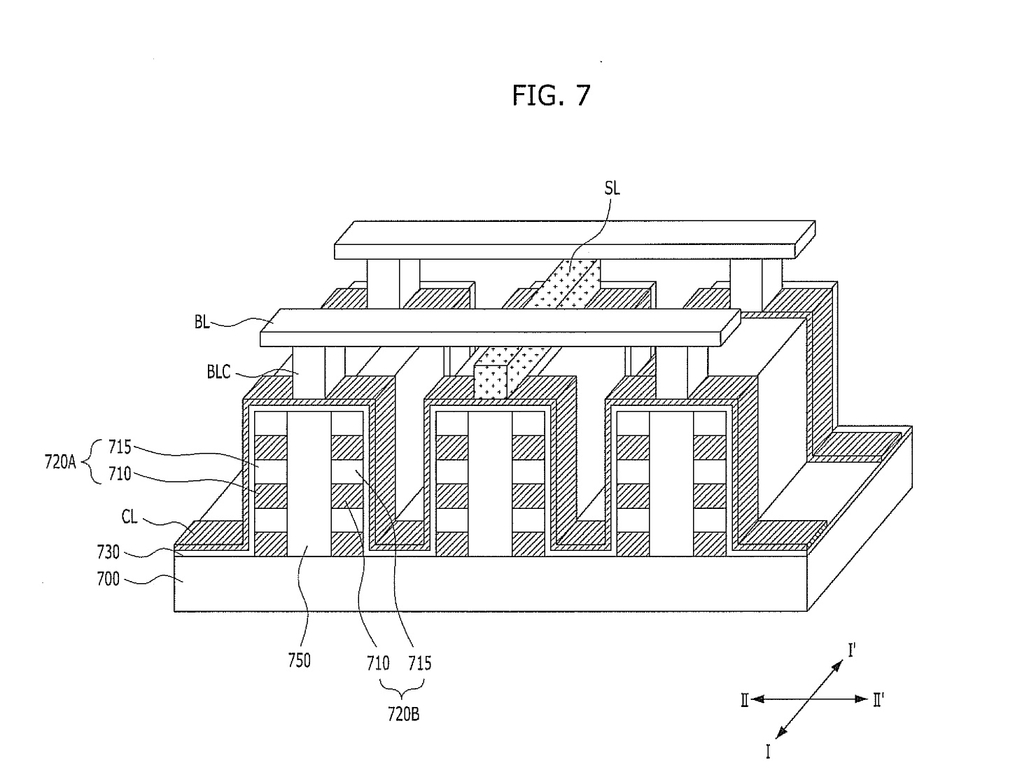

FIG. 7 is a perspective view illustrating a non-volatile memory device in accordance with a second exemplary embodiment of the present invention. Referring to FIG. 7, a method for fabricating the non-volatile memory device in accordance with the second exemplary embodiment of the present invention is described.

First, the structure of the non-volatile memory device in accordance with the second exemplary embodiment of the present invention is described.

Referring to FIG. 7, the non-volatile memory device includes a substrate 700, a pair of gate structures 720A and 720B, a second insulation layer 750 interposed between the pair of gate structures 720A and 720B, channel lines CL, a memory layer 730, bit line contacts BLC, source lines SL, and bit lines BL. Each of the gate structures 720A and 720B includes first insulation layers 710 and control gate layers 715 that are alternately stacked over the substrate 700 and extended in the first direction I-I′. The channel lines CL are stretched along the gate structures 720A and 720B and the second insulation layer 750 interposed between them in the second direction II-II′. The memory layer 730 is interposed between the gate structures 720A and 720B and the channel lines CL and includes sequentially-formed charge blocking layer, charge trapping layer, and tunnel insulation layer. The bit line contacts BLC are arrayed in the first direction and contact the top surfaces of the channel lines CL. The source lines SL extend in the first direction, contact the top surfaces of the channel lines CL, and are alternately disposed with rows of bit line contacts BLC that each extend in the first direction. The bit lines BL are formed over the bit line contacts BLC and extend in the second direction.

In the second exemplary embodiment of the present invention shown in FIG. 7, the channel lines are formed along the pair of gate structures (the first gate structure 720A and the second gate structure 750B) and the second insulation layer 750 formed between the first gate structure 720A and the second gate structure 750B in comparison to the channel lines formed along the gate structures 120 in the first exemplary embodiment shown in FIG. 1. Here, the memory layer 730 is interposed between the channels lines and the gate structures 720A and 720B and the second insulation layer 750 as a whole. Therefore, the number of memory cells coupled with a source/bit line in accordance with the second exemplary embodiment of the present invention is doubled as compared to the non-volatile memory device in accordance with the first exemplary embodiment of the present invention.

The top surfaces of channel lines contacting the source lines SL and the bit line contacts BLC are the top surface of the channel lines CL that are formed over the uppermost control gate layer 715 of the gate structures 720A and 720B.

A method for fabricating the semiconductor memory device in accordance with the second exemplary embodiment of the present invention is as follows.

Referring to FIG. 7, the semiconductor memory device in accordance with the second exemplary embodiment of the present invention is fabricated by alternately stacking the first insulation layers 710 and the control gate layers 715 over the substrate 700; forming the plurality of gate structures stretched in the first direction I-I′ by selectively etching the first insulation layers 710 and the control gate layers 715; filling the space between the etched gate structures with the second insulation layer 750; forming the memory layer 730 by sequentially stacking the charge blocking layer, the charge trapping layer, and the tunnel insulation layer (not shown) along the gate structures 720A and 720B and the second insulation layer 750; forming the channel layer over the memory layer 730; forming the channel lines CL extending in the second direction II-II′ by selectively etching the channel layer; forming the source lines SL that extend in the first direction and contact the top surfaces of the channel lines CL; forming bit line contacts BLC that are arrayed in the first direction and contact the top surfaces of the channel lines CL, where the arrays of bit line contacts BLC are alternately disposed with the source lines SL; and forming bit lines BL extending in the second direction over the bit line contacts BLC.

According to an exemplary embodiment of the present invention, a non-volatile memory device increase the degree of integration by stacking a plurality of memory cells in a vertical direction and controlling a threshold voltage of memory cells by forming channels with a uniform width.

While the present invention has been described with respect to the specific exemplary embodiments, it will be apparent to those skilled in the art that various changes and modifications may be made without departing from the spirit and scope of the invention as defined in the following claims.

What is claimed is:

1. A non-volatile memory device, comprising:
gate structures including first insulation layers that are alternately stacked with control gate layers over a substrate, wherein the gate structures extend in a first direction;
channel lines that each extend over the gate structures in a second direction different from the first direction;
a memory layer formed between the gate structures and the channel lines and arranged to trap charges by electrically insulating the gate structures from the channel lines;
bit line contacts forming rows that each extend in the first direction and contacting top surfaces of the channel lines;
source lines that each extend in the first direction and contact the top surfaces of the channel lines, wherein the source lines alternate with the rows of bit line contacts; and
bit lines that are each formed over the bit line contacts and extend in the second direction.

2. The non-volatile memory device of claim 1, wherein the control gate layers comprise a first type polysilicon and the first insulation layers comprise an oxide layer.

3. The non-volatile memory device of claim 1, wherein the channel lines comprise a polysilicon layer doped with the first type impurity or a second type impurity.

4. The non-volatile memory device of claim 1, wherein the channel lines are formed of a film so as to have a uniform channel width.

5. The non-volatile memory device of claim 1, wherein the memory layer comprises stacked layers of a charge blocking layer, a charge trapping layer, and a tunnel insulation layer.

6. The non-volatile memory device of claim 5, wherein the charge blocking layer comprises an oxide layer, the charge trapping layer comprises a nitride layer, and the tunnel insulation layer comprises an oxide layer.

7. The non-volatile memory device of claim 1, wherein the source lines comprise a metal.

8. A non-volatile memory device, comprising:
a pair of gate structures including first insulation layers that are alternately stacked with control gate layers over a substrate and each extend in a first direction;
a second insulation layer disposed between the pair of gate structures;
channel lines that each extend along the pair of gate structures and the second insulation layer in a second direction different from the first direction;
a memory layer disposed between the pair of gate structures and the second insulation layer as a whole and the channel lines to trap charges by electrically insulating the gate structures from the channel lines;
bit line contacts forming rows that each extend in the first direction and contacting top surfaces of the channel lines;
source lines that each extend in the first direction and contact the top surfaces of the channel lines, wherein the source lines alternate the rows of bit line contacts; and
bit lines that are formed over the bit line contacts and each extend in the second direction.

9. The non-volatile memory device of claim 8, wherein the memory layer comprises stacked layers of a charge blocking layer, a charge trapping layer, and a tunnel insulation layer.

10. The non-volatile memory device of claim 8, wherein the source lines comprise a metal.

11. A method for fabricating a non-volatile memory device, comprising:
alternately stacking first insulation layers with control gate layers over a substrate;
forming a plurality of gate structures that each extend in a first direction by selectively etching the first insulation layers and the control gate layers;
forming a memory layer along the gate structures;
forming a channel layer over the memory layer;
forming channel lines that each extend in a second direction different from the first direction by selectively etching the channel layer;
forming source lines that each extend in the first direction and contact the top surfaces of the channel lines;
forming bit line contacts in rows that each extend in the first direction, wherein the rows of bit line contacts contact the top surfaces of the channel lines and alternate with the source lines; and
forming bit lines that each extend in the second direction over the bit line contacts.

12. The method of claim 11, wherein the memory layer is formed by sequentially stacking a charge blocking layer, a charge trapping layer, and a tunnel insulation layer.

13. The method of claim 11, further comprising:
performing an ion implantation on the channel lines after the forming of the channel layer or the channel lines.

14. The method of claim 11, wherein the forming of the source lines comprises:
forming a third insulation layer that covers a substrate structure including the channel lines formed therein;
forming trenches that expose the top surfaces of the channel lines by selectively etching the third insulation layer; and
filling the trenches with a metallic material.

15. The method of claim 14, further comprising:
performing an ion implantation on the exposed top surface of the channel lines after the forming of the trenches.

16. A method for fabricating a non-volatile memory device, comprising:
alternately stacking first insulation layers with control gate layers over a substrate;
forming a plurality of gate structures that each extend in a first direction by selectively etching the first insulation layers and the control gate layers;
filling a space between the gate structures with a second insulation layer;
forming a memory layer along the gate structures and the second insulation layer;
forming a channel layer over the memory layer;
forming channel lines that each extend in a second direction different from the first direction by selectively etching the channel layer;
forming source lines that each extend in the first direction and contact the top surfaces of the channel lines;
forming bit line contacts in rows that that each extend in the first direction, wherein the rows of bits lines contact the top surfaces of the channel lines and alternate with the source lines; and
forming bit lines that each extend in the second direction over the bit line contacts.

17. The method of claim 16, wherein the memory layer is formed by sequentially stacking a charge blocking layer, a charge trapping layer, and a tunnel insulation layer.

18. The method of claim 16, further comprising:
performing an ion implantation on the channel lines, after the forming of the channel layer or the channel lines.

19. The method of claim 16, wherein the forming of the source lines comprises:
forming a third insulation layer that covers a substrate structure including the channel lines formed therein;
forming trenches that expose the top surfaces of the channel lines by selectively etching the third insulation layer; and
filling the trenches with a metallic material.

20. The method of claim 19, further comprising:
performing an ion implantation on the exposed top surface of the channel lines after the forming of the trenches.
